(19) United States
(12) Patent Application Publication
(10) Pub. No.: US 2011/0062492 A1
(43) Pub. Date: Mar. 17, 2011

(54) High-Quality Hetero-Epitaxy by Using Nano-Scale Epitaxy Technology

(75) Inventors: Chih-Hsin Ko, Fongshan City (TW); Clement Hsingjen Wann, Carmel, NY (US)

(73) Assignee: Taiwan Semiconductor Manufacturing Company, Ltd., Hsin-Chu (TW)

(21) Appl. No.: 12/831,852

(22) Filed: Jul. 7, 2010

Related U.S. Application Data
(60) Provisional application No. 61/242,625, filed on Sep. 15, 2009.

(51) Int. Cl. H01L 29/06

(52) U.S. Cl. 257/190; 257/183; 257/E29.024

(57) ABSTRACT

An integrated circuit structure includes a semiconductor substrate formed of a first semiconductor material; two insulators in the semiconductor substrate; and a semiconductor region between and adjoining sidewalls of the two insulators. The semiconductor region is formed of a second semiconductor material different from the first semiconductor material, and has a width less than about 50 nm.

This application claims the benefit of U.S. Provisional Application No. 61/242,625 filed on Sep. 15, 2009, entitled “High-Quality Hetero-Epitaxy by Using Nano-Scale Epitaxy Technology,” which application is hereby incorporated herein by reference.

### TECHNICAL FIELD

This disclosure relates generally to integrated circuit structures, and more particularly, to semiconductor materials having reduced defects and methods of forming the same.

### BACKGROUND

The speeds of metal-oxide-semiconductor (MOS) transistors are closely related to the drive currents of the MOS transistors, which drive currents are further closely related to the mobility of charges. For example, NMOS transistors have high drive currents when the electron mobility in their channel regions is high, while PMOS transistors have high drive currents when the hole mobility in their channel regions is high.

Germanium is a commonly known semiconductor material. The electron mobility and hole mobility of germanium are greater than that of silicon, which is the most commonly used semiconductor material in the formation of integrated circuits. Hence, germanium is an excellent material for forming integrated circuits. However, in the past, silicon gained more popularity since its oxide (silicon oxide) is readily usable in the gate dielectrics of MOS transistors. The gate dielectrics of the MOS transistors can be conveniently formed by thermally oxidizing silicon substrates. The oxide of germanium, on the other hand, is soluble in water, and hence is not suitable for the formation of gate dielectrics.

With the use of high-k dielectric materials in the gate dielectrics of the MOS transistors, however, the convenience provided by the silicon oxide is no longer a big advantage, and hence germanium is reexamined for use in the formation of MOS transistors.

In addition to germanium, compound semiconductor materials of group III and group V elements (referred to as III-V compound semiconductors hereinafter) are also good candidates for forming NMOS devices for their high electron mobility.

A challenge faced by the semiconductor industry is that it is difficult to form germanium films with high germanium concentrations or pure germanium films, and III-V compound semiconductor films. Particularly, it is difficult to form high-concentration germanium or III-V films with low defect densities and great thicknesses. Previous research has revealed that when a silicon germanium film is epitaxially grown from a blank silicon wafer, the critical thickness of the silicon germanium film reduces with the increase in the percentage of germanium in the silicon germanium film, wherein the critical thickness is the maximum thickness the silicon germanium film can reach without being relaxed. When relaxation occurs, the lattice structure will be broken, and defects will be generated. For example, when formed on blank silicon wafers, the critical thickness of a silicon germanium film with a 20 percent germanium percentage may be only about 10 nm to about 20 nm. To make things worse, when the germanium percentage increases to 40, 60, and 80 percent, the critical thicknesses are further reduced to about 6-8 nm, 4-5 nm, and 2-3 nm, respectively. When the thickness of germanium films exceeds the critical thickness, the number of defects increases significantly. Accordingly, it is not feasible to form germanium or III-V compound semiconductor films on blank silicon wafers for the purpose of forming MOS transistors, particularly fin field-effect transistors (FinFETs).

Semiconductor re-growth was explored to improve the quality of germanium or III-V compound semiconductor films. One of the semiconductor re-growth processes comprises blanket depositing a dislocation-blocking mask on a semiconductor substrate, and forming an opening in the dislocation-blocking mask until the semiconductor substrate is exposed through the opening. A re-growth is then performed to form a re-growth region in the opening, which growth region is formed of a semiconductor material such as germanium or a III-V compound semiconductor. Although the quality of the re-growth region is generally improved over the blanket-formed films formed of the same material as the re-growth region, defects such as dislocations were still observed.

### SUMMARY

In accordance with one aspect of the embodiment, an integrated circuit structure includes a semiconductor substrate formed of a first semiconductor material; two insulators in the semiconductor substrate; and a semiconductor region between and adjoining sidewalls of the two insulators. The semiconductor region is formed of a second semiconductor material different from the first semiconductor material, and has a width less than about 50 nm.

Other embodiments are also disclosed.

### BRIEF DESCRIPTION OF THE DRAWINGS

For a more complete understanding of the present disclosure, and the advantages thereof, reference is now made to the following descriptions taken in conjunction with the accompanying drawings, in which:

FIGS. 1A through 5 are cross-sectional views of intermediate stages in the manufacturing of a high-quality hetero-structure in accordance with an embodiment.

### DETAILED DESCRIPTION OF ILLUSTRATIVE EMBODIMENTS

The making and using of the embodiments of the present disclosure are discussed in detail below. It should be appreciated, however, that the embodiments provide many applicable inventive concepts that can be embodied in a wide variety of specific contexts. The specific embodiments discussed are merely illustrative of specific ways to make and use the disclosure, and do not limit the scope of the disclosure.

Novel methods of epitaxially growing low-defect semiconductor materials are presented. The intermediate stages of manufacturing an integrated circuit structure in accordance with an embodiment are illustrated. The variations of the embodiment are discussed. Throughout the various views and illustrative embodiments, like reference numbers are used to designate like elements.

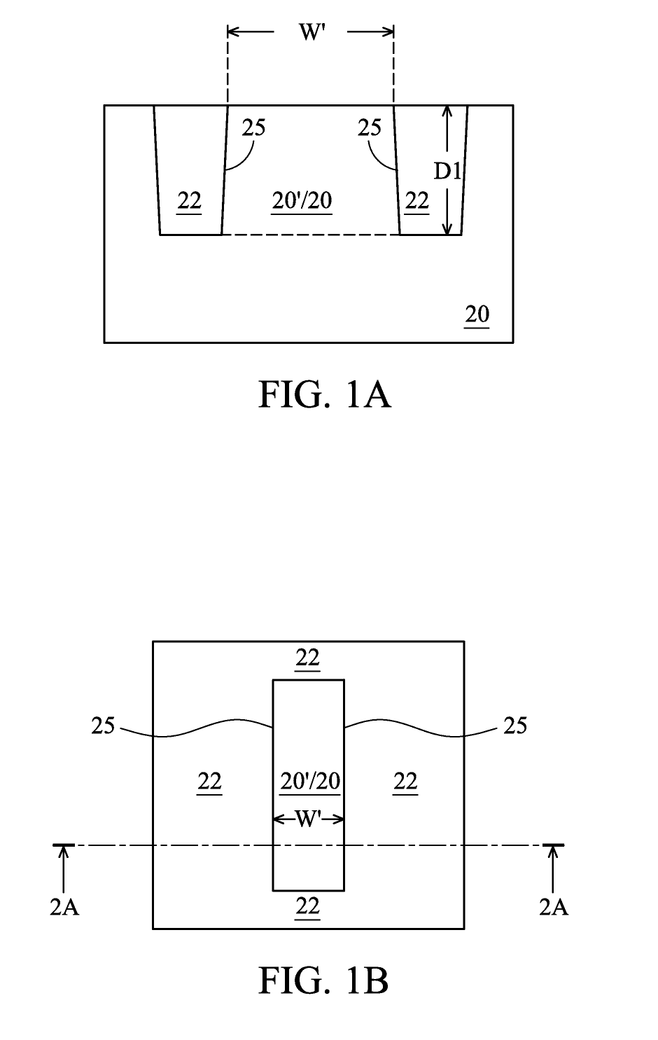

Referring to FIG. 1A, substrate 20 is provided. Substrate 20 may be a semiconductor substrate formed of commonly used semiconductor materials such as silicon. Insulators such as shallow trench isolation (STI) regions 22 are formed in substrate 20. Depth D1 of STI regions 22 may be between about 50 nm and about 300 nm, or even between about 100 nm and about 400 nm. It is realized, however, that the dimensions recited throughout the description are merely examples, and may be changed if different formation technologies are used. STI regions 22 may be formed by recessing semiconductor substrate 20 to form openings, and then filling the openings with dielectric materials.

STI regions 22 include two neighboring regions (which may be portions of a continuous region as illustrated in FIG. 1B) with their sidewalls facing each other. Portion 20′ of substrate 20 is between, and adjoins, the two neighboring STI regions 22. Width W′ of substrate portion 20′ may be small. In an embodiment, width W′ is less than about 50 nm. Width W′ may also be less than about 30 nm, or between about 30 nm and about 5 nm.

FIG. 1B illustrates a top view of the structure shown in FIG. 1A, wherein FIG. 1A is obtained from a plane crossing line 2A-2A in FIG. 1B. STI regions 22 may encircle portion 20′ of substrate 20. Substrate portion 20′ may have a rectangular shape with two long sides and two short sides. It is desirable that the sidewalls, particularly longer sidewalls 25, do not extend along [100] and [111] directions of substrate 20. In an exemplary embodiment, sidewalls 25 may extend along [110)] direction of substrate 20. Width W′ may be equal to the length of the shorter side of portion 20′.

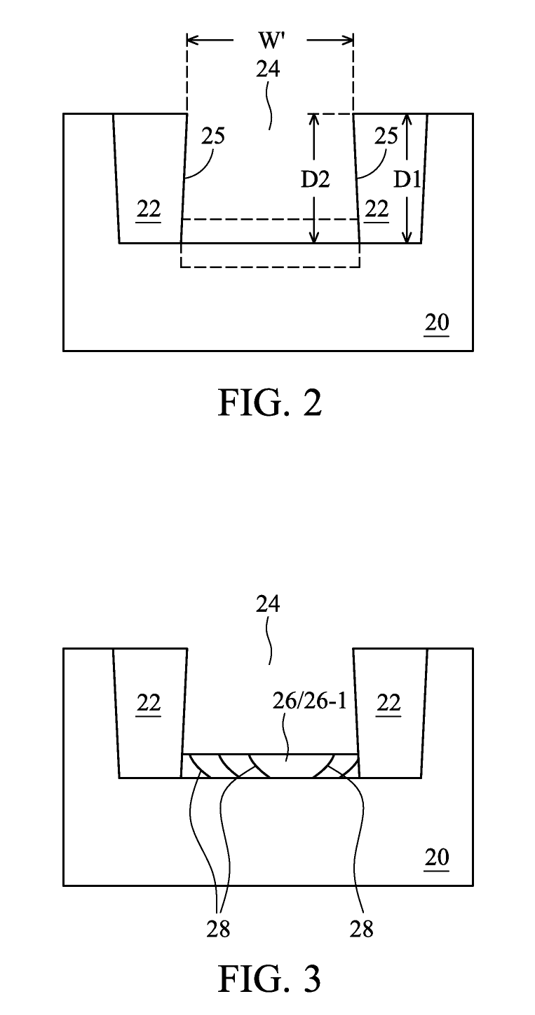

Referring to FIG. 2, substrate portion 20′ is removed, forming opening 24. Sidewalls 25 of STI regions 22 are hence exposed to opening 24. In an embodiment, the bottom of opening 24 is level with the bottoms of STI regions 22. In alternative embodiments, the bottom of opening 24 (as shown by dotted lines) may be lower than or higher than the bottoms of STI regions 22. Accordingly, the aspect ratio (depth D2 of opening 24 to width W′) of opening 24 may be increased or decreased, as desirable. For example, the aspect ratio of opening 24 may be less than 1.8, or even less than about 1. The aspect ratio of opening 24 may be as low as 1.

Referring to FIG. 3, semiconductor region 26, which comprises a material having a lattice constant different from that of semiconductor substrate 20, is grown in opening 24. The methods for forming semiconductor region 26 include, for example, selective epitaxial growth (SEG). In an embodiment, semiconductor region 26 comprises silicon germanium, which may be expressed as Si₁₋ₓGeₓ, wherein x is the atomic percentage of germanium in the silicon germanium, and may be greater than 0 and equal to or less than 1. When x is equal to 1, semiconductor region 26 is formed of pure germanium. In alternative embodiments, semiconductor region 26 comprises a compound semiconductor material comprising group III and group V elements (III-V compound semiconductor), which may include, but is not limited to, GaAs, InP, GaN, InGaAs, InAlAs, GaSb, AlSb, AlAs, AlP, GaP, combinations thereof, and multi-layers thereof.

In an embodiment, after a layer (denoted as layer 26-1) of semiconductor region 26 is epitaxially grown, an anneal is performed. The anneal may be a flash anneal, a laser anneal, a rapid thermal anneal, or the like. The anneal may cause the dislocations, for example, threading dislocations as illustrated as 28, to glide horizontally. With the gliding of the dislocations, dislocations 28 may meet the sidewalls 25 of STI regions 22, and are blocked. When layers of semiconductor region 26 that are over layer 26-1 are grown, the blocked dislocations will no longer grow, and the number of the dislocations will decrease.

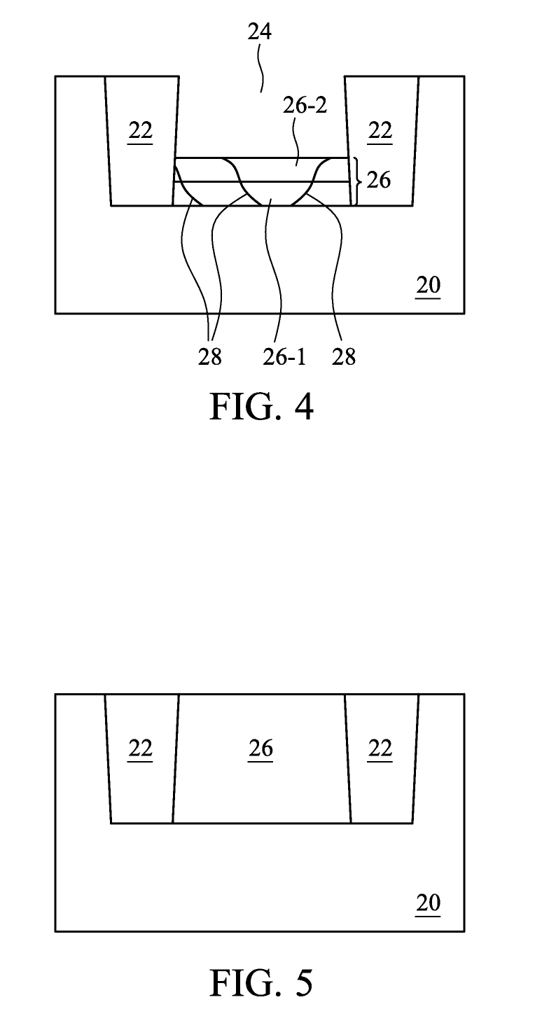

In FIG. 4, an additional layer (denoted as 26-2) of semiconductor region 26 is epitaxially grown. The additional layer 26-2 may have a same composition as, or have a slightly different composition than, the underlying layer 26-1. If layer 26-1 and semiconductor substrate 20 have a first lattice mismatch, and layer 26-2 and semiconductor substrate 20 have a second lattice mismatch, the second lattice mismatch may be greater than, or equal to, the first lattice mismatch. In an embodiment, layers 26-1 and 26-2 are both SiGe layers, with layer 26-2 having a greater germanium percentage than the underlying layer 26-1. After the formation of layer 26-2, an additional anneal may be performed, so that more threading dislocations may glide and be blocked by sidewalls 25 of STI regions 22.

In an embodiment, the above-discussed epitaxial growth and anneal may be repeated multiple times. Further, for the growth of each of the layers, the composition of the respective semiconductor material may be the same as in the underlying layer(s), or has a greater lattice mismatch with semiconductor substrate 20 than the underlying layer(s). In alternative embodiments, after a certain number of growth-anneal cycles, no more anneals are performed, and semiconductor region 26 is continuously grown to a level higher than the top surface of STI regions 22.

The epitaxial growth is performed until the top surface of semiconductor region 26 is higher than the top surfaces of STI regions 22. A chemical mechanical polish (CMP) may be performed to level the top surfaces of STI regions 22 with the top surface of semiconductor region 26, resulting in the structure as shown in FIG. 5. Alternatively, only one anneal, instead of multiple anneals, is performed. The only one anneal may be performed before or after the CMP. After the structure as shown in FIG. 5 is formed, a metal-oxide-semiconductor (MOS) device (not shown) may be formed, for example, by forming a gate dielectric on semiconductor region 26, forming a gate electrode on the gate dielectric, and implanting portions of semiconductor region 26 to form source and drain regions.

It has been found that with the width W′ (FIGS. 1A and 1B) being reduced to 50 nm or below, the number of dislocations in the re-grown semiconductor region may be significantly reduced. Experiment results have revealed that with the width W′ being less than 50 nm, a desirable number of dislocations can be achieved even if the aspect ratio of opening 24 (FIG. 2) is less than 1.8, and particularly if the aspect ratio is less than 1, as contrary to the requirement of conventional formation methods.

Although the embodiments and their advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps. In addition, each claim constitutes a separate embodiment, and the combination of various claims and embodiments are within the scope of the invention.

What is claimed is:

1. An integrated circuit structure comprising:
a semiconductor substrate formed of a first semiconductor material;
two insulators in the semiconductor substrate; and
a semiconductor region between and adjoining sidewalls of the two insulators, wherein the semiconductor region is formed of a second semiconductor material being different from the first semiconductor material, and has a width less than about 50 nm.

2. The integrated circuit structure of claim 1, wherein the width of the semiconductor region is less than about 30 nm.

3. The integrated circuit structure of claim 1, wherein an aspect ratio of the semiconductor region is less than 1.8.

4. The integrated circuit structure of claim 3, wherein the aspect ratio is less than about 1.

5. The integrated circuit structure of claim 1, wherein the semiconductor substrate is a silicon substrate, and wherein the second semiconductor material comprises silicon germanium.

6. The integrated circuit structure of claim 1, wherein the semiconductor substrate is a silicon substrate, and wherein the second semiconductor material is a compound semiconductor (III-V compound semiconductor) material comprising group III and group V elements.

7. The integrated circuit structure of claim 1, wherein upper portions of the semiconductor region have greater lattice mismatches with the semiconductor substrate than lower portions of the semiconductor region.

8. The integrated circuit structure of claim 1, wherein the semiconductor region has a top surface level with top surfaces of the two insulators.

9. An integrated circuit structure comprising:
a silicon substrate;
two shallow trench isolation (STI) regions in the silicon substrate; and
a semiconductor region between and adjoining opposite sidewalls of the two STI regions, wherein the semiconductor region comprises a material selected from the group consisting essentially of germanium and a III-V compound semiconductor material, and wherein the semiconductor region has a width less than about 50 nm, and has an aspect ratio less than 1.8.

10. The integrated circuit structure of claim 9, wherein the width of the semiconductor region is less than about 30 nm.

11. The integrated circuit structure of claim 9, wherein the aspect ratio is less than about 1.

12. The integrated circuit structure of claim 9, wherein the semiconductor region comprises germanium.

13. The integrated circuit structure of claim 9, wherein the semiconductor region comprises a III-V compound semiconductor material.

14. An integrated circuit structure comprising:
a silicon substrate formed of a first semiconductor material;
two shallow trench isolation (STI) regions in the silicon substrate and comprising opposite sidewalls facing each other, and wherein a distance between the opposite sidewalls is less than about 50 nm; and
a III-V compound semiconductor region between and adjoining the opposite sidewalls of the two STI regions, wherein the III-V compound semiconductor region has an aspect ratio less than 1.0.

15. The integrated circuit structure of claim 14, wherein the distance is less than about 30 nm.

16. The integrated circuit structure of claim 14, wherein upper portions of the III-V compound semiconductor region have greater lattice mismatches with the silicon substrate than lower portions of the III-V compound semiconductor region.

17. The integrated circuit structure of claim 14, wherein the III-V compound semiconductor region has a top surface level with top surfaces of the two STI regions.
